(19) United States
(12) Patent Application Publication
(10) Pub. No.: US 2026/0173377 A1
(43) Pub. Date: Jun. 18, 2026

(54) METHOD FOR MANUFACTURING SEMICONDUCTOR DEVICE AND SEMICONDUCTOR DEVICE

(71) Applicant: Kioxia Corporation, Tokyo (JP)

(72) Inventors: Yuta KAMIYA, Nagoya Aichi (JP); Tatsunori ISOGAI, Yokkaichi Mie (JP); Atsushi FUKUMOTO, Kuwana Mie (JP); Junichi KANEYAMA, Yokkaichi Mie (JP); Koki HAYASHI, Yokkaichi Mie (JP)

(73) Assignee: Kioxia Corporation, Tokyo (JP)

(21) Appl. No.: 19/312,920

(22) Filed: Aug. 28, 2025

(30) Foreign Application Priority Data
Dec. 16, 2024 (JP) 2024-220141

(51) Int. Cl. H10B 43/27; H10B 43/10; H10B 43/30; H10D 30/01; H10D 30/69; H10D 64/01; H10D 64/68

(52) U.S. Cl. CPC H10B 43/27; H10B 43/30; H10D 30/0413; H10D 30/693; H10D 64/037; H10D 64/693; H10B 43/10

(57) ABSTRACT

A method includes forming a stack including a sacrificial layer and an insulating layer stacked in a first direction; forming a hole penetrating the stack; forming a first film along an inner surface of the hole; forming a second film on the first film; forming a third film on the second film; forming a first charge storage film on the third film; forming a fourth film on the first charge storage film; forming a semiconductor layer on the fourth film; removing the sacrificial layer exposing the first film; exposing the second film by removing the first film; selectively forming a fifth film on the insulating layer and the first film; exposing the first charge storage film by removing the second film and the third film; selectively forming a second charge storage film on the exposed first charge storage film; and forming a sixth film on the second charge storage film.

### CROSS-REFERENCE TO RELATED APPLICATION(S)

This application is based upon and claims the benefit of priority from Japanese Patent Application No. 2024-220141, filed Dec. 16, 2024, the entire contents of which are incorporated herein by reference.

### FIELD

Embodiments described herein relate generally to a method for manufacturing a semiconductor device and a semiconductor device.

### BACKGROUND

A NAND flash memory configured such that a memory cell is three-dimensionally disposed is known as a semiconductor device. In this NAND flash memory, a memory hole penetrates a stack in which a plurality of electrode layers and a plurality of insulating layers are alternately stacked on each other. A charge storage layer and a semiconductor layer are provided in this memory hole, and in this manner, a memory string is formed, in which a plurality of memory cells is connected in series. Data is stored in the memory cell by controlling the amount of charge stored in the charge storage layer.

### DESCRIPTION OF THE DRAWINGS

FIG. 1A is a schematic cross-sectional view of a memory cell of a semiconductor device of a first embodiment.

FIG. 1B is a schematic cross-sectional view of the memory cell of the semiconductor device of the first embodiment.

FIG. 2 is a cross-sectional view illustrating a step of manufacturing the semiconductor device of the first embodiment.

FIG. 3 is a cross-sectional view illustrating a step of manufacturing the semiconductor device of the first embodiment.

FIG. 4 is a cross-sectional view illustrating a step of manufacturing the semiconductor device of the first embodiment.

FIG. 5 is a cross-sectional view illustrating a step of manufacturing the semiconductor device of the first embodiment.

FIG. 6 is a cross-sectional view illustrating a step of manufacturing the semiconductor device of the first embodiment.

FIG. 7 is a cross-sectional view illustrating a step of manufacturing the semiconductor device of the first embodiment.

FIG. 8 is a cross-sectional view illustrating a step of manufacturing the semiconductor device of the first embodiment.

FIG. 9 is a cross-sectional view illustrating a step of manufacturing the semiconductor device of the first embodiment.

FIG. 10 is a cross-sectional view illustrating a step of manufacturing the semiconductor device of the first embodiment.

FIG. 11 is a cross-sectional view illustrating a step of manufacturing the semiconductor device of the first embodiment.

FIG. 12 is a cross-sectional view illustrating a step of manufacturing a semiconductor device of a second embodiment.

FIG. 13 is a cross-sectional view illustrating a step of manufacturing the semiconductor device of the second embodiment.

### DETAILED DESCRIPTION

Embodiments provide a method for manufacturing a semiconductor device and a semiconductor device, with which a film structure in a desired shape can be obtained.

In general, according to one embodiment, a method for manufacturing the semiconductor device according to the present embodiment includes forming a stack including a sacrificial layer and an insulating layer stacked on top of each other in a first direction; forming a hole penetrating the stack in the first direction; forming a first film extending along an inner surface of the hole, the first film including an insulator; forming a second film on the first film; forming a third film on the second film, the third film including an insulator; forming a first charge storage film on the third film; forming a fourth film on the first charge storage film, the fourth film including an insulator; forming a semiconductor layer on the fourth film; removing the sacrificial layer to expose the first film; exposing the second film by removing the first film in a region from which the sacrificial layer is removed; selectively forming a fifth film on the insulating layer and the first film, the fifth film including an insulator; exposing the first charge storage film by removing the second film and the third film in the region from which the sacrificial layer is removed; selectively forming a second charge storage film on the exposed first charge storage film; and forming a sixth film on the second charge storage film, the sixth film including an insulator.

Hereinafter, embodiments according to the present disclosure will be described with reference to the drawings. The present embodiments do not limit the present disclosure. The drawings are schematic or conceptual, and the proportion and the like of each portion are not necessarily the same as the actual ones. In the description and the drawings, elements similar to those previously described with reference to a preceding figure are denoted by the same reference signs, and the detailed description thereof will be appropriately omitted.

### First Embodiment

A semiconductor device of a first embodiment is a three-dimensional NAND flash memory.

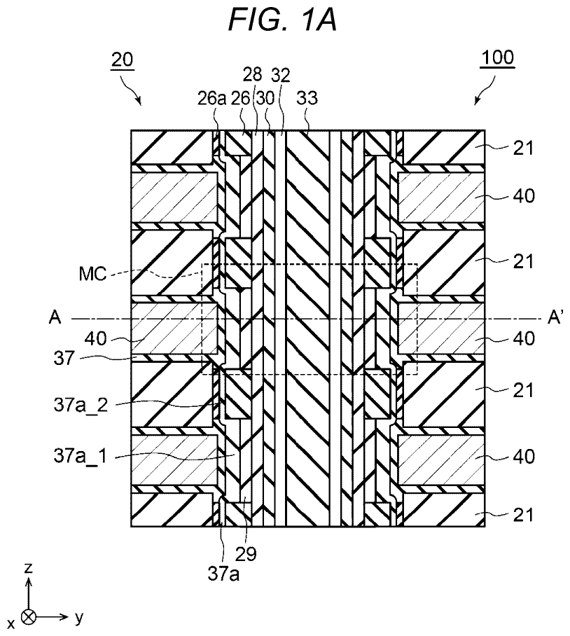

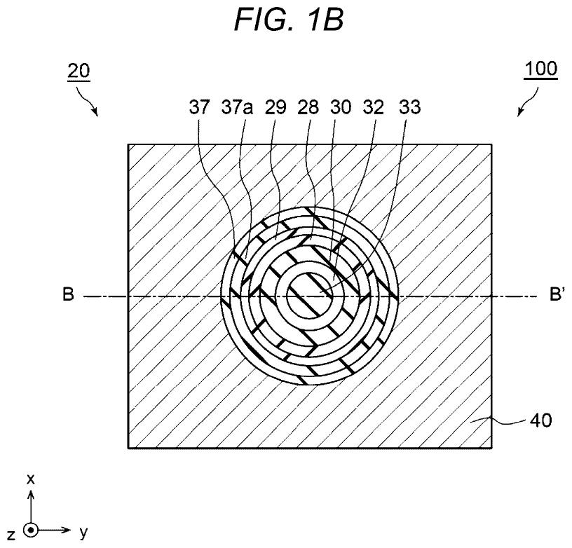

FIGS. 1A and 1B are schematic cross-sectional views of a memory cell array 100 of the semiconductor device of the first embodiment. FIGS. 1A and 1B illustrate the cross sections of a plurality of memory cells MC in a single memory string in the memory cell array 100.

FIG. 1A is a yz cross-sectional view of the memory cell array 100. FIG. 1A illustrates a cross section taken along BB′ line in FIG. 1B. FIG. 1B is a xy cross-sectional view of the memory cell array 100. FIG. 1B illustrates a cross section taken along AA′ line in FIG. 1A. In FIG. 1A, a region surrounded by a broken line is a single memory cell MC.

As illustrated in FIGS. 1A and 1B, the memory cell array 100 includes a plurality of word lines 40, a semiconductor layer 32, a plurality of insulating layers 21, a tunnel insulating film 30, a charge storage film 28, a plurality of charge storage films 29, a block film 37a, a plurality of block films 37, a core insulating film 33, and a plurality of cover films 26. The plurality of word lines 40 and the plurality of insulating layers 21 form a stack 20.

The memory cell array 100 is provided, for example, on a semiconductor substrate (not illustrated). The semiconductor substrate has a surface parallel with the x direction and the y direction.

The word lines 40 and the insulating layers 21 are alternately stacked on each other in the z direction (first direction) on the semiconductor substrate. The word lines 40 are disposed apart from each other in the z direction. The word lines 40 are repeatedly disposed apart from each other in the z direction. The plurality of word lines 40 and the plurality of insulating layers 21 form the stack 20. The word line 40 functions as a control electrode for a memory cell transistor.

The word line 40 is a plate-shaped conductor. The word line 40 is made, for example, of metal, metal nitride, metal carbide, or semiconductor. The word line 40 is made, for example, of tungsten (W) or molybdenum (Mo). The thickness of the word line 40 in the z direction is, for example, 5 nm or more and 20 nm or less.

The insulating layer 21 separates the word line 40 and the word line 40 from each other. The insulating layer 21 electrically separates the word line 40 and the word line 40 from each other.

The insulating layer 21 is made, for example, of oxide, oxynitride, or nitride. The insulating layer 21 is made, for example, of silicon oxide. The thickness of the insulating layer 21 in the z direction is, for example, 5 nm or more and 20 nm or less.

The semiconductor layer 32 is provided in the stack 20. The semiconductor layer 32 extends in the z direction. The semiconductor layer 32 extends in a direction perpendicular to the surface of the semiconductor substrate.

The semiconductor layer 32 penetrates the stack 20. The semiconductor layer 32 is surrounded by the plurality of word lines 40. The semiconductor layer 32 is, for example, in a cylindrical shape. The semiconductor layer 32 functions as a channel for the memory cell transistor.

The semiconductor layer 32 is made, for example, of polycrystalline semiconductor. The semiconductor layer 32 is made, for example, of polycrystalline silicon.

The tunnel insulating film 30 is provided between the semiconductor layer 32 and the word line 40. The tunnel insulating film 30 is provided between the semiconductor layer 32 and the plurality of word lines 40. The tunnel insulating film 30 is provided between the semiconductor layer 32 and the charge storage film 29. The tunnel insulating film 30 is provided between the semiconductor layer 32 and the charge storage film 28.

The tunnel insulating film 30 has a function allowing charge passage according to voltage applied between the word line 40 and the semiconductor layer 32.

The tunnel insulating film 30 contains, for example, silicon (Si) and oxygen (O). The tunnel insulating film 30 contains, for example, silicon (Si), oxygen (O), and nitrogen (N).

The tunnel insulating film 30 contains, for example, silicon oxide or silicon oxynitride. The tunnel insulating film 30 is, for example, a film stack of a silicon oxide film, a silicon oxynitride film, and a silicon oxide film.

The thickness of the tunnel insulating film 30 in the y direction is, for example, 3 nm or more and 8 nm or less.

The charge storage film 28 is provided between the tunnel insulating film 30 and the charge storage film 29. The charge storage film 28 is provided between the tunnel insulating film 30 and the insulating layer 21. The charge storage film 28 contacts the charge storage film 29.

The charge storage film 28 functions as a seed film when the charge storage film 29 is formed by vapor phase epitaxy.

The charge storage film 28 contains silicon (Si) and nitrogen (N). The charge storage film 28 contains, for example, silicon nitride. The charge storage film 28 is, for example, a silicon nitride film.

The charge storage film 28 contains, for example, silicon (Si), nitrogen (N), and oxygen (O). The charge storage film 28 contains, for example, silicon oxynitride.

The thickness of the charge storage film 28 in the y direction is, for example, 1 nm or more and 5 nm or less.

The charge storage film 29 is provided between the tunnel insulating film 30 and the word line 40. The charge storage film 29 is provided between the tunnel insulating film 30 and the block film 37. The plurality of charge storage films 29 is separated from each other. The cover film 26 is sandwiched between adjacent two of the charge storage films 29 in the z direction.

The charge storage film 29 has a function of trapping and storing charge. The charge is, for example, an electron. According to the amount of charge stored in the charge storage film 29, the threshold voltage of the memory cell transistor changes. Using this change in the threshold voltage, the single memory cell MC can store data.

For example, as the threshold voltage of the memory cell transistor changes, voltage for turning on the memory cell transistor changes. For example, when the state of a high threshold voltage is defined as data “0” and the state of a low threshold voltage is defined as data “1”, the memory cell MC can store 1-bit data of “0” and “1”.

The charge storage film 29 contains silicon (Si) and nitrogen (N). The charge storage film 29 contains, for example, silicon nitride. The charge storage film 29 is, for example, a silicon nitride film.

The block film 37a has a first portion 37a_1 and a second portion 37a_2. In the example illustrated in FIG. 1A, the first portion 37a_1 and the second portion 37a_2 are connected to each other. The first portion 37a_1 and the second portion 37a_2 are not necessarily connected to each other.

The first portion 37a_1 of the block film 37a is provided between the charge storage film 29 and the block film 37.

The first portion 37a_1 of the block film 37a has a function of blocking current flowing between the charge storage film 29 and the word line 40.

The second portion 37a_2 of the block film 37a is provided between the insulating layer 21 and the charge storage film 29.

The block film 37a (including the first portion 37a_1 and the second portion 37a_2) contains, for example, silicon and oxygen. The block film 37a contains, for example, silicon oxide. The block film is, for example, a silicon oxide film. The second portion 37a_2 according to the first embodiment contains nitrogen, as described later.

The block film 37 is provided between the first portion 37a_1 of the block film 37a and the word line 40. The block film 37 contacts the insulating layer 21 in the z direction.

The block film 37 has a function of blocking current flowing between the charge storage film 29 and the word line 40.

The block film 37 contains, for example, aluminum oxide. The block film 37 is, for example, an aluminum oxide layer.

The core insulating film 33 is provided in the stack 20. The core insulating film 33 extends in the z direction. The core insulating film 33 penetrates the stack 20. The core insulating film 33 is surrounded by the semiconductor layer 32. The core insulating film 33 is surrounded by the plurality of word lines 40. The core insulating film 33 is in a columnar shape. The core insulating film 33 is, for example, in a circular columnar shape.

The core insulating film 33 is made, for example, of oxide, oxynitride, or nitride. The core insulating film 33 contains, for example, silicon oxide. The core insulating film 33 is, for example, a silicon oxide layer.

The cover film 26 is provided between the charge storage film 28 and the insulating layer 21. The cover film 26 contacts the charge storage film 28 and the insulating layer 21. The cover film 26 contains, for example, silicon and oxygen. The cover film 26 is, for example, a silicon oxide film.

The thickness of the cover film 26 in the y direction is, for example, 3 nm or more and 8 nm or less.

A cover film 26a is provided between the insulating layer 21 and the second portion 37a_2 of the block film 37a. The cover film 26a contains, for example, silicon and oxygen. The cover film 26a is, for example, a silicon oxide film.

The thickness of the cover film 26a in the y direction is, for example, 2 nm or more and 3 nm or less. Thus, in the y direction intersecting the z direction, the cover film 26 is thicker than the cover film 26a.

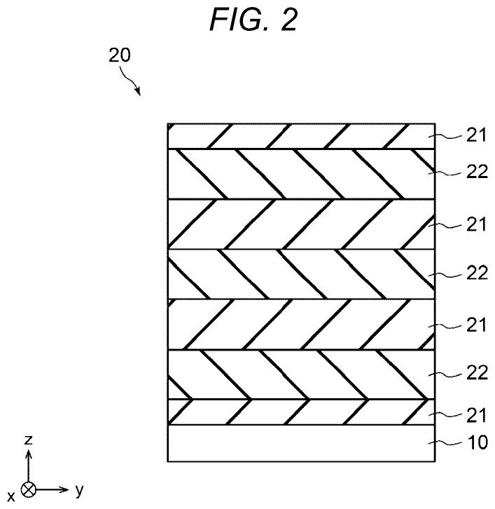

The semiconductor device according to the first embodiment will be described with reference to FIGS. 2 to 11. The semiconductor device of this embodiment is manufactured by the following method, for example. First, as illustrated in FIG. 2, the insulating layers 21 and the sacrificial layers 22 are alternately stacked on each other on a semiconductor substrate 10. In this manner, the stack 20 is formed, in which these layers are stacked on each other in the z direction (up-down direction in the figure). The insulating layer 21 is, for example, a silicon oxide layer. The sacrificial layer 22 is, for example, a silicon nitride layer.

The insulating layer 21 and the sacrificial layer 22 are formed, for example, by a chemical vapor deposition (CVD) method. Part of the insulating layer 21 is an interlayer insulating layer.

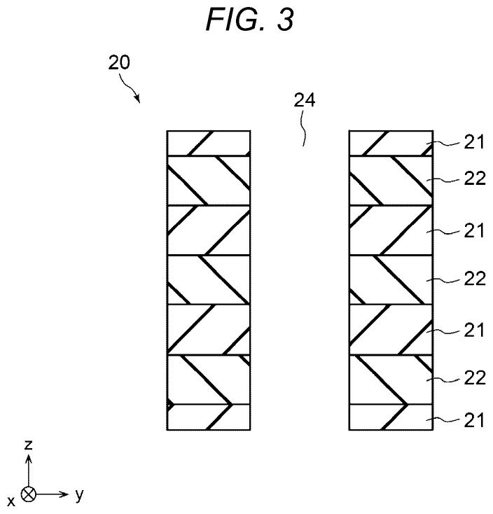

Next, as illustrated in FIG. 3, a memory hole 24 is formed along the z direction in the stack 20. In drawings subsequent to FIG. 3, no semiconductor substrate 10 is illustrated. This memory hole 24 penetrates the stack 20 formed of the insulating layers 21 and the sacrificial layers 22. This memory hole 24 is formed, for example, using a lithography method and a reactive ion etching (RIE) method.

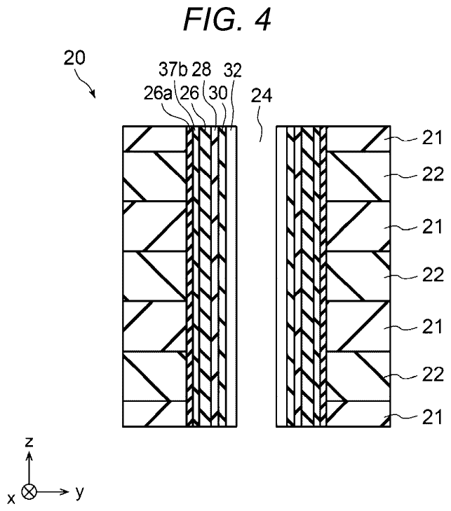

Next, as illustrated in FIG. 4, on the inner wall of the memory hole 24, a silicon oxide film having, for example, a thickness of 2 nm or more and 3 nm or less is formed as the cover film 26a. The cover film 26a also has the function of a stopper film. On this cover film 26a, a silicon nitride film having, for example, a thickness of 2 nm is formed as a cover film 37 b. That is, the cover film 37b contains silicon and nitrogen. The cover film 37b also has the function of a stopper film. On this cover film 37b, a silicon oxide film having, for example, a thickness of 5 nm is formed as the cover film 26. The cover film 26 also has the function of a stopper film. On this cover film 26, a silicon nitride film having, for example, a thickness of 2 nm is formed as the charge storage film 28 forming part of a charge storage film. On this charge storage film 28, a silicon oxynitride film having, for example, a thickness of 5 nm is formed as the tunnel insulating film 30. On this tunnel insulating film 30, the semiconductor layer 32 having, for example, a thickness of 7 nm is formed. The cover film 26, the charge storage film 28, and the tunnel insulating film 30 are formed, for example, by the CVD method. As the material of the semiconductor layer 32, polysilicon is typically used. However, in terms of surface roughness, a crystallization method is used, in which amorphous silicon is formed at a low temperature (for example, about 500 degrees) and then thermal treatment is performed at 800 degrees or more. The materials of the cover films 26a, 37b, 26, the charge storage film 28, and the tunnel insulating film 30 are examples, and as long as the structure of the semiconductor device of the embodiment described with reference to FIGS. 1A and 1B can be implemented, are not particularly limited.

The cover film 37b is not limited to the silicon nitride film. The cover film 37b includes a material having an etching selectivity with respect to the cover films 26, 26a which are the silicon oxide films. The cover film 37b includes, for example, a material turnable into an oxide film by oxidation treatment at a subsequent step.

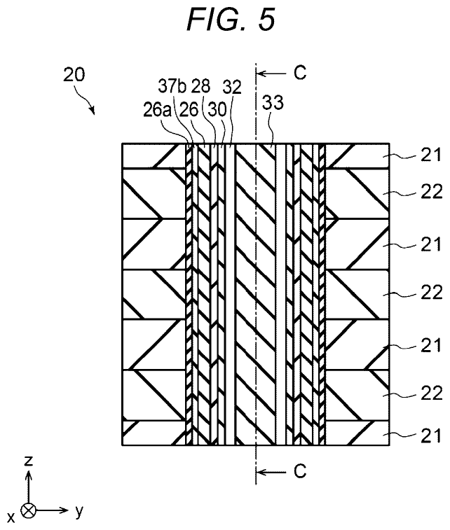

Next, as illustrated in FIG. 5, the memory hole 24 is filled with the core insulating film 33. The core insulating film 33 is, for example, a silicon oxide film. In the following description, the cross section is symmetric with respect to a center line C-C illustrated in FIG. 5, and therefore, the left side of the cross section with respect to the center line C-C will be described. In the following drawings, no tunnel insulating film 30, semiconductor layer 32, and core insulating film 33 are illustrated.

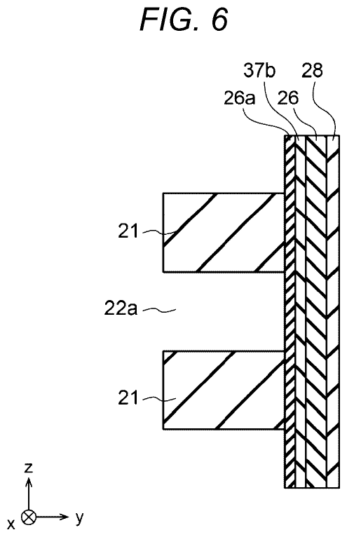

Thereafter, a groove penetrating the stack 20 is opened at the periphery of the memory hole 24, and the sacrificial layers 22 are removed through this groove. By the removal of the sacrificial layers 22, the cover film 26a is exposed. For the removal of the sacrificial layers 22, a heated phosphoric acid chemical solution is normally used. By this treatment with the chemical solution, a gap 22a is formed after the removal of the silicon nitride layer. The gap 22a tracing the shape of the original sacrificial layer 22 is formed (see FIG. 6).

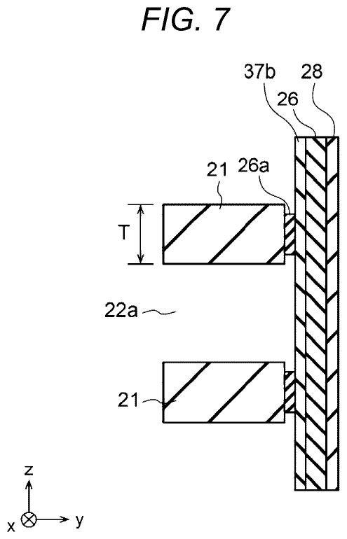

Next, as illustrated in FIG. 7, the cover film 26a is partially removed with a hydrofluoric acid (HF) chemical solution diluted by about 0.5%. In this manner, part of the cover film 37b is exposed in the gap 22a.

Part of the insulating layer 21 is also scraped, and therefore, the film thickness T of the insulating layer 21 in the z direction is decreased. In the example illustrated in FIG. 7, the cover film 26a is more removed in the z direction as compared to the insulating layer 21. The etching rate of the cover film 26a is higher than the etching rate of the insulating layer 21. An etching rate difference is adjusted, for example, by a film quality (film density), an impurity concentration, and the like. The cover film 26a is formed, for example, with a relatively-low film density. Moreover, the insertion position of the cover film 37b is determined according to a deflection-allowable film thickness of the insulating layer 21.

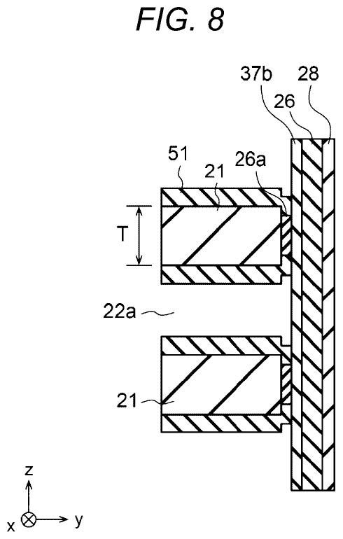

Next, as illustrated in FIG. 8, a cover film 51 is selectively formed on the insulating layer 21 and the cover film 26a. More specifically, the cover film 51 is selectively grown on the insulating layer 21 and the cover film 26a by selective growth (area selective deposition: ASD).

The cover film 51 contains, for example, silicon, oxygen, and carbon. The cover film 51 is, for example, a silicon oxycarbide film (SiOC film) or a carbon-containing silicon oxide film. The material of the cover film 51 is not limited thereto. The cover film 51 includes a material having an etching rate lower than the etching rate of the cover film 26.

The cover film 51 can make up for the decrement of the film thickness T due to the scraping of part of the insulating layer 21. This can extend a time of processing the cover film 26 in a subsequent step.

The selective growth of the cover film 51 is performed, for example, in such a manner that an inhibitor selectively adsorbed onto the cover film 37b which is the silicon nitride film is supplied and a precursor containing silicon (Si) and a precursor containing carbon (C) or a precursor containing both silicon and carbon are supplied.

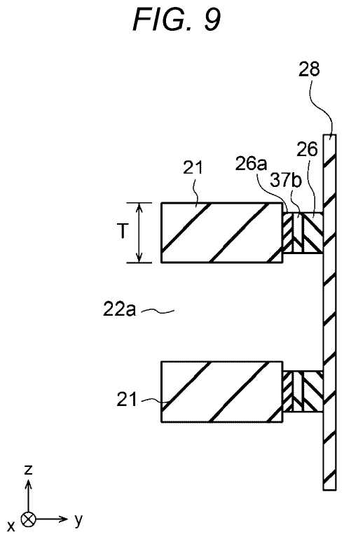

Next, as illustrated in FIG. 9, the cover film 37b is partially removed. In this manner, part of the cover film 26 is exposed. Subsequently, the cover film 26 is partially removed. In this manner, part of the charge storage film 28 is exposed. Moreover, part of the cover film 26 is removed, and the cover film 51 is also removed. Part of the cover film 51 may remain, but the entirety thereof is preferably removed.

Part of the cover film 26 and the cover film 51 are removed, for example, with a hydrofluoric acid chemical solution.

In a case where the film thickness T is too small, silicon oxide (SiO₂) may be formed on the insulating layer 21 by selective growth for making up for such a small film thickness.

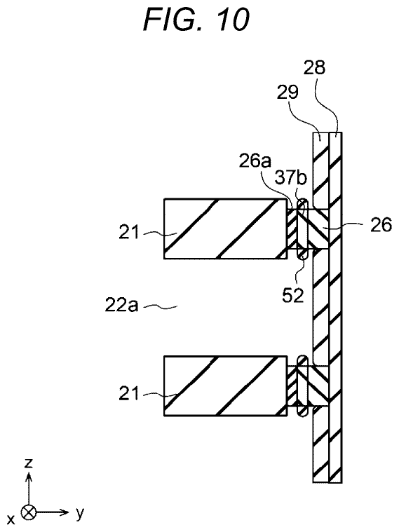

Next, as illustrated in FIG. 10, the charge storage film 29 is selectively formed on the charge storage film 28. More specifically, the charge storage film 29 is grown by selective growth. Silicon nitride (SiN) may also be grown on the exposed cover film 37b to form a film 52.

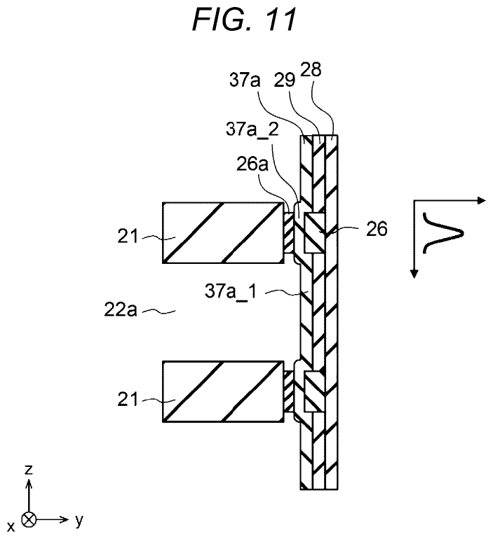

Next, as illustrated in FIG. 11, the block film 37a is formed on the charge storage film 29. More specifically, the first portion 37a_1 and second portion 37a_2 of the block film 37a are formed by oxidizing part of the charge storage film 29 and the cover film 37b. That is, silicon oxide is formed by oxidation of silicon nitride. The oxidation treatment is performed until the thickness of the charge storage film 29 in the y direction reaches a desired film thickness. Unoxidized part of the charge storage film 29 remains as the charge storage film 29.

Silicon nitride swells when oxidized, and the second portion 37a_2 formed of the cover film 37b and the first portion 37a_1 formed of the charge storage film 29 are connected to each other. However, the first portion 37a_1 and the second portion 37a_2 are not necessarily connected to each other.

In the example illustrated in FIG. 11, the film 52 is also oxidized, and in this manner, the first portion 37a_1 and the second portion 37a_2 are easily connected to each other.

Since the block film 37a is formed by the oxidation of part of the silicon nitride film, the block film 37a may contain nitrogen.

A graph illustrated on the right side in FIG. 11 is a graph schematically showing the concentration of nitrogen in the second portion 37a_2. The vertical axis indicates a position in the z direction. The horizontal axis indicates the concentration of nitrogen.

The concentration of nitrogen is the highest at a center portion of the second portion 37a_2 in the z direction, and decreases toward upper and lower end portions in the z direction. That is, the concentration of nitrogen at the center portion of the second portion 37a_2 is higher than the concentration of nitrogen at the end portion closer to the word line 40 with respect to the center portion of the second portion 37a_2. This is because the closer to the center portion, the less nitrogen is pulled out during the oxidation treatment.

The cover film 37b which is the silicon nitride film is formed such that the nitrogen concentration thereof is lower than that of the charge storage film 28 which is the silicon nitride film. With this configuration, a probability of silicon nitride remaining due to incomplete oxidation of the second portion 37a_2 of the block film 37a and charge being trapped therein can be reduced.

The charge storage film of the embodiment includes the charge storage film 28 and the charge storage film 29. By this treatment, the charge storage film 29 as part of the charge storage layer is formed with a thickness in the y direction of about 1 nm to about 2 nm. With this configuration, in the y direction in the gap 22a, the thickness of the charge storage film in the y direction is the sum of the thickness (about 1 nm to about 3 nm) of the charge storage film 28 and the thickness (about 1 nm to about 2 nm) of the charge storage film 29. However, the charge storage film in the region provided with no charge storage film 29 is the charge storage film 28, and the thickness thereof is about 1 nm to about 3 nm. That is, the charge storage film 28 forming the charge storage film is continuous in a direction (z direction) in which the semiconductor layer 32 extends, but the charge storage film 29 is divided in the z direction by the cover film 26. Thus, a quasi-divided structure of the charge storage film is formed.

Thereafter, the block film 37 containing, for example, aluminum oxide covers the bottom and side surfaces of the gap 22a. Barrier metal containing, for example, TiN may cover the block film 37. Next, the gap 22a is filled with a wiring material such as tungsten (W), and the word line (electrode) 40 is formed. In this manner, the semiconductor device is completed.

As described above regarding the quasi-divided structure of the charge storage film, the sum of the thicknesses of the charge storage film 28 and the charge storage film 29 in the y direction is greater than the thickness of the charge storage film 28 in the y direction.

As described above, according to the first embodiment, the cover film 37b is exposed by the removal of the cover film 26a in the region from which the sacrificial layer 22 is removed. Moreover, the cover film 51 is selectively formed on the insulating layer 21 and the cover film 26a. The cover film 51 can selectively increase the thickness of the insulating layer 21 with the cover film 37b remaining exposed. The thickness of the insulating layer 21 is increased to a target film thickness, and thereafter, the charge storage film 28 is exposed by the removal of the cover film 37b and the cover film 26. The charge storage film 29 is selectively formed on the exposed charge storage film 28, and in this manner, a desired divided shape can be obtained.

When the quasi-divided structure of the charge storage film is formed, the thickness of the stopper film (cover film) as the silicon oxide film may be increased in order to locate the cell portion in the memory hole 24, for example, in consideration of back-to-back arrangement. However, in some cases, it is difficult to process the thick cover film into a proper shape.

When the stack 20 is formed, in order to reduce the scraping of the insulating layer 21 at the time of the removal of the cover film, such that SiOC layers are stacked on the upper and lower surfaces of the insulating layer 21, a cost increases.

On the other hand, in the first embodiment, the cover film 37b which is the silicon nitride film is inserted between the cover film 26a and the cover film 26 which are the silicon oxide films. Moreover, the cover film 51 containing SiOC is formed by selective growth on the insulating layer 21. This can reduce interference between adjacent cells and the cost while ensuring the film thickness of the insulating layer 21.

### Second Embodiment

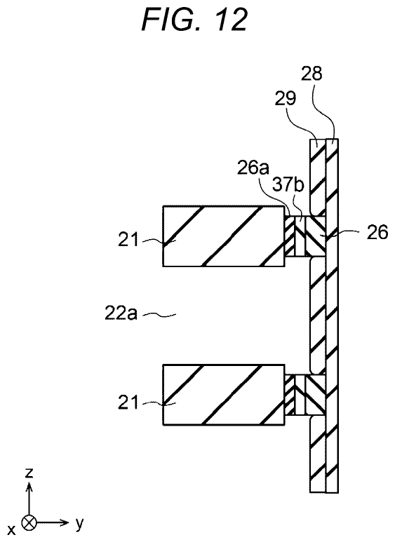

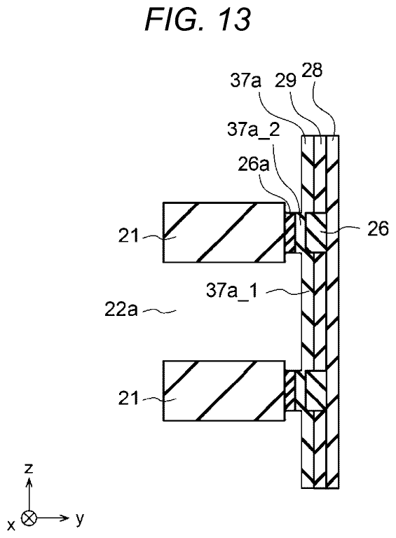

A semiconductor device according to a second embodiment will be described with reference to FIGS. 12 and 13. The second embodiment is different from the first embodiment in the material of the cover film 37b. Thus, no film 52 is formed in the second embodiment.

The cover film 37b contains, for example, silicon (Si). The steps illustrated in FIGS. 2 to 9 in the first embodiment are the same as steps in the second embodiment.

The cover film 37b and the cover film 26 are partially removed such that part of the charge storage film 28 is exposed (see FIG. 9), and thereafter, the charge storage film 29 is selectively formed on the charge storage film 28 as illustrated in FIG. 12. More specifically, the charge storage film 29 is grown by selective growth.

Next, as illustrated in FIG. 13, the first portion 37a_1 and second portion 37a_2 of the block film 37a are formed by oxidizing part of the charge storage film 29 and the cover film 37b. The step illustrated in FIG. 13 is the same as the step illustrated in FIG. 11.

The cover film 37b according to the second embodiment has no charge trapping properties even when remaining due to insufficient oxidation.

As in the second embodiment, the material of the cover film 37b may be changed. The semiconductor device according to the second embodiment can obtain effects similar to those of the first embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A method for manufacturing a semiconductor device, comprising:
forming a stack including a sacrificial layer and an insulating layer stacked on top of each other in a first direction;
forming a hole penetrating the stack in the first direction;
forming a first film extending along an inner surface of the hole;
forming a second film on the first film;
forming a third film on the second film;
forming a first charge storage film on the third film;
forming a fourth film on the first charge storage film;
forming a semiconductor layer on the fourth film;
removing the sacrificial layer and the first film to expose the second film;
selectively forming a fifth film on the insulating layer and the first film;
exposing the first charge storage film by removing the second film and the third film in the region from which the sacrificial layer is removed;
selectively forming a second charge storage film on the exposed first charge storage film; and
forming a sixth film on the second charge storage film.

2. The method for manufacturing the semiconductor device according to claim 1, wherein an etching rate of the fifth film is lower than an etching rate of the third film.

3. The method for manufacturing the semiconductor device according to claim 1, wherein the fifth film includes silicon, oxygen, and carbon.

4. The method for manufacturing the semiconductor device according to claim 1, wherein the removing the third film in the region from which the sacrificial layer is removed includes removing the third film and removing the fifth film.

5. The method for manufacturing the semiconductor device according to claim 1, wherein the second film includes silicon.

6. The method for manufacturing the semiconductor device according to claim 5, wherein
the first charge storage film includes nitrogen,
the second film further includes nitrogen, and
a concentration of nitrogen in the second film is lower than a concentration of nitrogen in the first charge storage film.

7. The method for manufacturing the semiconductor device according to claim 1, wherein the selectively forming the second charge storage film on the exposed first charge storage film includes forming the second charge storage film and forming a seventh film on the second film.

8. The method for manufacturing the semiconductor device according to claim 1, wherein each of the first film and the third film includes silicon and oxygen.

9. The method for manufacturing the semiconductor device according to claim 1, wherein the second charge storage film includes silicon and nitrogen.

10. The method for manufacturing the semiconductor device according to claim 1, wherein the fourth film is a tunnel insulating film.

11. The method for manufacturing the semiconductor device according to claim 1, further comprising:
forming an electrode layer in which the sacrificial layer is removed, after forming the sixth film.

12. The method for manufacturing the semiconductor device according to claim 1, wherein the fourth film is a tunnel insulating film and the sixth film is a block film.

13. A semiconductor device comprising:
a stack including an electrode layer and an insulating layer stacked on top of each other in a first direction;
a semiconductor layer disposed along the first direction in the stack;
a first insulating film disposed along the first direction between the stack and the semiconductor layer;
a first charge storage film disposed along the first direction between the stack and the first insulating film;
a second charge storage film disposed between the electrode layer and the first charge storage film;
a second insulating film disposed between the insulating layer and the first charge storage film;
a third insulating film having a first portion and a second portion, wherein the first portion is disposed between the electrode layer and the second charge storage film and the second portion is disposed between the insulating layer and the second insulating film; and
a fourth insulating film disposed between the insulating layer and the second portion,
wherein the first portion and the second portion each include silicon and oxygen, and
the second portion further includes nitrogen.

14. The semiconductor device according to claim 13, wherein in a second direction intersecting the first direction, the second insulating film is thicker than the fourth insulating film.

15. The semiconductor device according to claim 13, wherein a concentration of the nitrogen at a center portion of the second portion is higher than a concentration of the nitrogen at an end portion closer to the electrode layer with respect to the center portion of the second portion.

16. The semiconductor device according to claim 13, wherein the second portion is connected to the first portion.

17. The semiconductor device according to claim 13, wherein the second charge storage film is in contact with the second insulating film in the first direction.

18. The semiconductor device according to claim 13, wherein the first insulating film is a tunnel insulating film and the third insulating film is a block film.
